(19) United States
(12) Patent Application Publication
(10) Pub. No.: US 2025/0210909 A1
(43) Pub. Date: Jun. 26, 2025

(54) Automation Component

(71) Applicant: Siemens Aktiengesellschaft, Muenchen (DE)

(72) Inventors: Stefan GÖRLICH, Illschwang (DE); Stefan HUBMANN, Sulzbach-Rosenberg (DE)

(21) Appl. No.: 18/989,205

(22) Filed: Dec. 20, 2024

(30) Foreign Application Priority Data
Dec. 21, 2023 (EP) 23219363

(51) Int. Cl. H01R 13/52; H01R 25/00; H01R 27/02

(52) U.S. Cl. CPC H01R 13/5219; H01R 25/006; H01R 27/02

(57) ABSTRACT

An automation component for industrial automation includes first and second surfaces seamlessly arranged in one piece on a center line of first and second fastening openings, wherein the center line is formed as a ridge such that the first and second surfaces each respectively extend as inclined planes to first and second eaves edges starting from the center line, connectors in the first and second surfaces are each structured such that a thread for a connector is integrated in the surfaces or in the upper part and a circular contact surface, where the circular contact surface is arranged in the inclined plane such that an axis of symmetry extends vertically such that the contact surface for a screw-in plug connector to be screwed in for the connector becomes formed as a flat annular contact surface upon which the screw-in plug connector is sealable with a hygienic seal.

### BACKGROUND OF THE INVENTION

### 1. Field of the Invention

The invention relates to an automation component for industrial automation having a housing comprising an upper part and a lower part, where the upper part and the lower part are structured such that, in order to fasten the automation component to a mounting surface, the housing has a first fastening opening and a second fastening opening, and where a plurality of data connectors are arranged in the upper part, and where each of the plurality of data connectors are configured to accommodate screw-in plug connectors.

### 2. Description of the Related Art

When automation devices are used in medical settings or in the food and beverage industry, for example, they must meet specific requirements relating to hygiene. These requirements substantially relate to the ease of cleaning of the devices used.

The following automation devices or components are known from the prior art:
Balluff Network Interface IO-Link BNI IOL-252-000-Z013 according to the installation instructions.
Digital Module AXL E IOL DI16 M12 6P.
SIMATIC ET 200AL, DI 8x 24 V DC, 8XM8, Degree of protection IP67 according to the data sheet dated May 21, 2020 or according to the device manual A5E32349561-AD dated August 2021.

All these conventional automation components have the drawback that their data, power and signal connectors create a dirt-collecting edge around the data, power and signal connectors when their screw-in plug connectors are plugged in and screwed in.

### SUMMARY OF THE INVENTION

It is an object of the invention to provide an automation component that meets the hygiene requirements of the food industry.

This and other objects and advantages are achieved in accordance with the invention by an automation component in which the upper part is formed flat, where a first surface and a second surface of the upper part are arranged in one piece and seamlessly together on a center line, which extends through the centers of a first fastening opening and a second fastening opening, such that the center line is thus formed as a ridge of the upper part, the upper part is formed such that the first surface extends as an inclined plane to a first eaves edge starting from the center line and the second surface extends as a further inclined plane to a second eaves edge starting from the center line, where data, power and signal connectors in the first and second surfaces are each configured such that a thread for a data, power and signal connector is integrated in the surfaces or in the upper part and a circular contact surface formed as a hollow cylinder is arranged around the thread. The hollow cylinder is in turn arranged in the inclined plane such that an axis of symmetry of the hollow cylinder runs vertically, where this causes the contact surface for a screw-in plug connector to be screwed in for the data, power and signal connector to be formed as a flat annular contact surface on which the screw-in plug connector can be sealed with a hygienic seal.

The upper part is advantageously structured similarly to a gable roof, preferably with an inclination of greater than or equal to 3 degrees, which allows water to drain off easily. These structures prevent the adhesion of impurities and the resulting contamination of the automation component. A hygienic seal as a sealing element lies flush with the outer surface of the hollow cylinder, and the thickness of the sealing element at this point is slightly greater than a corresponding recess on the screw-in plug connector so that, when installed, the sealing element is arranged compressed between the annular contact surface and the mating bearing of the recess on the screw-in plug connector such that a gap-free transition is formed therebetween.

The housing and thus the upper part and the lower part are advantageously formed such that, in a preferred installation position in which the fastening openings lie perpendicularly one above the other, the housing tapers in the direction of the second fastening opening starting from the first fastening opening. This allows liquids to drain away quickly.

In order to enhance cleanliness, the housing is formed such that all surfaces are shaped such that accumulation of impurities is avoided or minimized. This is achieved by eliminating sharp edges or indentations.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

The drawing shows an exemplary embodiment of the invention, in which:

FIG. 1 shows a perspective view of an automation component in accordance with the invention;

FIG. 2 shows the upper part of the automation component of FIG. 1;

FIG. 3 shows a different view of the upper part of the automation component of FIG. 1;

FIG. 4 shows a sectional view of the upper part of the automation component of FIG. 1; and

FIG. 5 shows a perspective view of a screw-in plug connector screwed to a data connector in accordance with the invention.

### DETAILED DESCRIPTION OF THE EXEMPLARY EMBODIMENTS

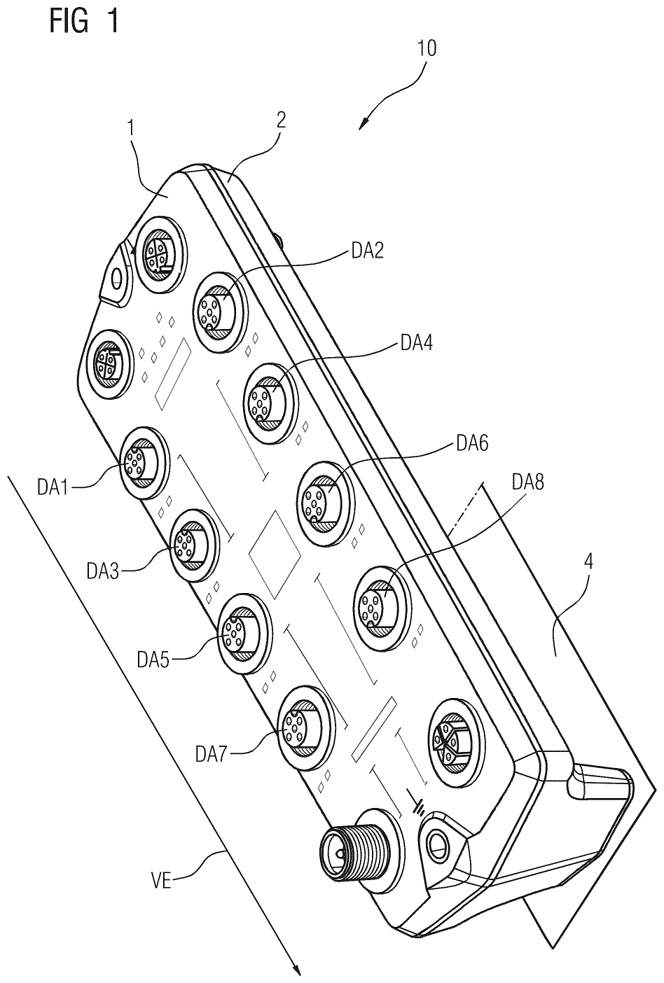

FIG. 1 shows an automation component 10. The automation component 10 is formed as an I/O assembly for industrial automation. The automation component 10 has a housing 3 comprising an upper part 1 and a lower part 2. The upper part 1 and the lower part 2 are structured such that, in order to fasten the automation component 10 to a mounting surface 4, the housing 3 has a first fastening opening 21 and a second fastening opening 22. The upper part 1 has a plurality of connectors (DA1, . . . ,DA8); here the focus is substantially on the signal connectors for the actuators and sensors, but the same applies to data, power and signal connectors. These connectors (DA1, . . . ,DA8) are configured to accommodate screw-in plug connectors S. A preferred installation direction VE provides for the automation component 10 to be attached or screwed to the mounting surface 4, which is formed as a wall.

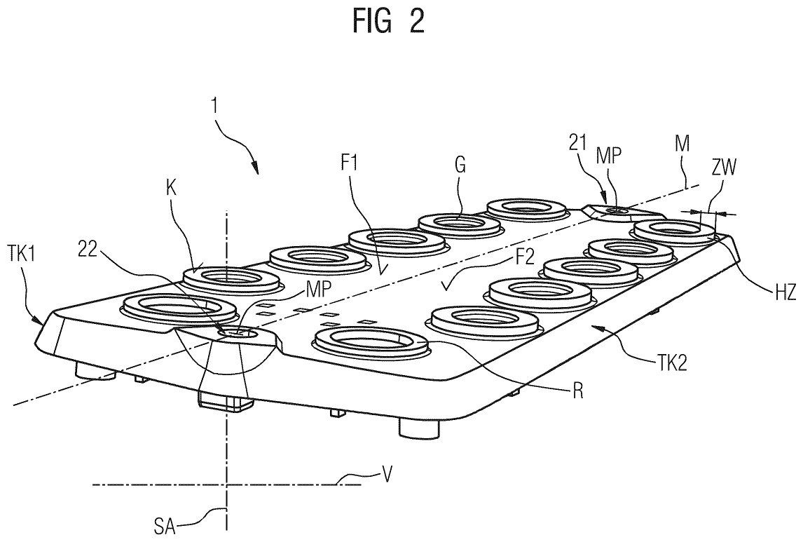

The upper part 1 is formed flat, where a first surface F1 and a second surface F2 are arranged on a center line M, where FIG. 2 illustrates this arrangement.

In FIG. 2, the upper part 1 is structured such that the first surface F1 extends in an inclined plane to a first eaves edge TK starting from the center line M and the second surface F2 extends in a further inclined plane to a second eaves edge TK starting from the center line M.

The connectors (DA1, . . . , DA8) are each formed in the first surface F1 and in the second surface F2 such that a thread G for a connector (DA1, . . . ,DA8) is integrated in the surfaces F1,F2. A circular contact surface K formed as a hollow cylinder HZ is arranged around the respective thread G. The hollow cylinder HZ is in turn arranged in the inclined plane such that an axis of symmetry SA of a hollow cylinder HZ extends vertically. This enables the contact surface K to be formed as a flat annular contact surface K for a screw-in plug connector S that can be screwed in for the respective connector (DA1, . . . ,DA8). The screw-in plug connector S can be sealed on this contact surface K with a hygienic seal D.

The hollow cylinder HZ is arranged in the surface F1,F2 such that the contact surface K protrudes in a raised manner from the surface both on the side of the center line M and on the side of the eaves edge TK1, TK2 and is formed in one piece with the surface F1, F2, where the transition of the hollow cylinder HZ to the surface F1,F2 is provided with a curve R.

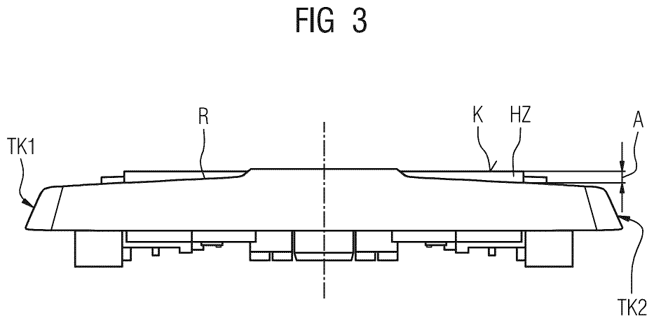

FIG. 3 illustrates the raised protrusion of the hollow cylinder HZ once again. The distance A shows the raised protrusion of the hollow cylinder HZ from the surface F1,F2.

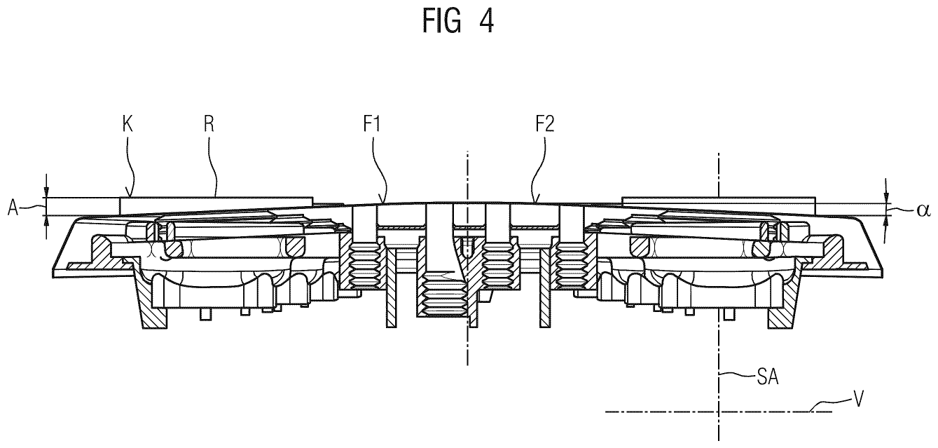

FIG. 4 shows an alternative view. Here, it can again be clearly seen in the sectional view that the contact surface K of the hollow cylinder HZ protrudes in a raised manner from the first surface F1 or the second surface F2 at a distance A. Starting from the center line M, which can be regarded as a ridge for the upper part 1, the first surface F1 and the second surface F2 have an angle of inclination α, preferably of 3 degrees or more.

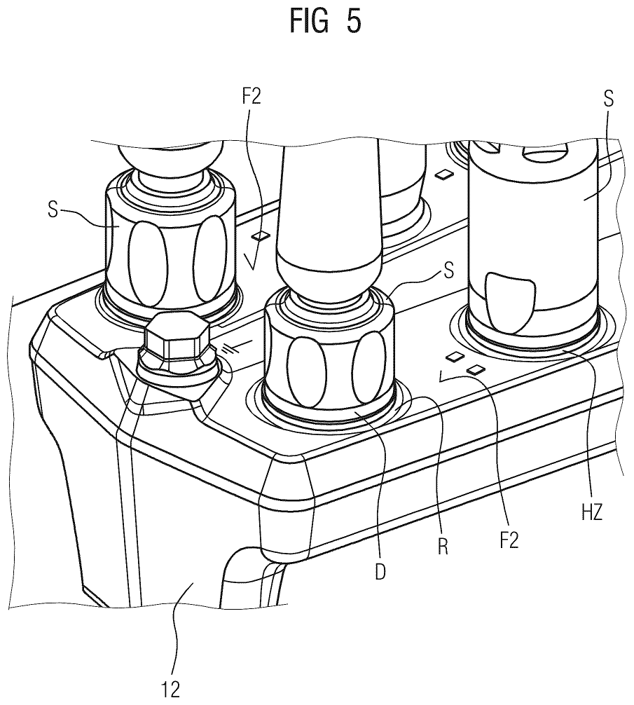

FIG. 5 illustrates how the screw-in plug connector S is arranged on the contact surface K with its sealing element D. A hygienic seal D as a sealing element lies flush with the outer surface of the hollow cylinder HZ, and the thickness of the sealing element D at this point is slightly greater than a corresponding recess on the screw-in plug connector S so that, when installed, the sealing element is arranged compressed between the annular contact surface K and the mating bearing of the recess on the screw-in plug connector S such that a gap-free transition is formed therebetween.

Thus, while there have been shown, described and pointed out fundamental novel features of the invention as applied to a preferred embodiment thereof, it will be understood that various omissions and substitutions and changes in the form and details of the methods described and the devices illustrated, and in their operation, may be made by those skilled in the art without departing from the spirit of the invention. For example, it is expressly intended that all combinations of those elements that perform substantially the same function in substantially the same way to achieve the same results are within the scope of the invention. Moreover, it should be recognized that structures and/or elements shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

What is claimed is:

1. An automation component for industrial automation, the automation component comprising:
a housing including an upper part and a lower part, the upper part and the lower part being configured such that the housing has a first fastening opening and a second fastening opening to fasten the automation component to a mounting surface;
a plurality of connectors arranged in the upper part, each of the plurality of connectors being configured to accommodate screw-in plug connectors;
wherein the upper part is formed flat;
wherein a first surface and a second surface of the upper part are arranged in one piece and seamlessly together on a center line which extends through centers of the first fastening opening and the second fastening opening, the center line being formed as a ridge of the upper part, the upper part being formed such that the first surface extends in an inclined plane to a first eaves edge starting from the center line and the second surface extends in a further inclined plane to a second eaves edge starting from the center line;
wherein the plurality of connectors are arranged in the first surface and in the second surface and are each configured such that a thread for a connector is integrated in one of (i) each of the first and second surfaces and (ii) the upper part and a circular contact surface formed as a hollow cylinder is arranged around the thread, the hollow cylinder is arranged in the inclined plane such that an axis of symmetry of the hollow cylinder extends vertically, such that the contact surface for a screw-in plug connector is caused to be screwed in for each of the plurality of connectors to be formed as a flat annular contact surface upon which the screw-in plug connector is sealable with a hygienic seal.

2. The automation component as claimed in claim 1, wherein the hollow cylinder is arranged in the first and surfaces such that the contact surface protrudes in a raised manner from the first and second surfaces on a side of the center line and on a side of the eaves edge and is formed in one piece with the first and second surfaces; and wherein a transition of the hollow cylinder to the surface is provided with a curve.

3. The automation component as claimed in claim 1, wherein the housing including the upper part and the lower part are formed such that, in a preferred installation position in which the fastening openings lie perpendicularly one above the other, the housing tapers in a direction of the second fastening opening starting from the first fastening opening.

4. The automation component as claimed in claim 2, wherein the housing including the upper part and the lower part are formed such that, in a preferred installation position in which the fastening openings lie perpendicularly one above the other, the housing tapers in a direction of the second fastening opening starting from the first fastening opening.

5. The automation component as claimed in claim 1, wherein the housing is configured such that all surfaces are shaped such that accumulation of impurities is avoided or minimized.

6. The automation component as claimed in claim 2, wherein the housing is configured such that all surfaces are shaped such that accumulation of impurities is avoided or minimized.

7. The automation component as claimed in claim 3, wherein the housing is configured such that all surfaces are shaped such that accumulation of impurities is avoided or minimized.
